(19) United States
(12) Patent Application Publication
(10) Pub. No.: US 2021/0242351 A1
(43) Pub. Date: Aug. 5, 2021

(54) EFFICIENT THREE-DIMENSIONAL DESIGN FOR LOGIC APPLICATIONS USING VARIABLE VOLTAGE THRESHOLD THREE-DIMENSIONAL CMOS DEVICES

(71) Applicant: Tokyo Electron Limited, Tokyo (JP)

(72) Inventors: MARK I. GARDNER, CEDAR CREEK, TX (US); H. Jim FULFORD, Marianna, FL (US); Anton DEVILLIERS, Albany, NY (US)

(73) Assignee: Tokyo Electron Limited, Tokyo (JP)

(21) Appl. No.: 17/074,125

(22) Filed: Oct. 19, 2020

Related U.S. Application Data
(63) Continuation of application No. 16/656,911, filed on Oct. 18, 2019.
(60) Provisional application No. 63/046,932, filed on Jul. 1, 2020.

(51) Int. Cl. H01L 29/792; H01L 27/11578; H01L 27/092

(52) U.S. Cl. CPC H01L 29/7926; H01L 27/0922; H01L 27/11578

(57) ABSTRACT

A charge trap field-effect transistor (FET) includes multiple layers of dielectric material defining a charge trapping layer. A p-doped (or n-doped) source region and a p-doped (or n-doped) drain region are connected via a nano-channel, the nano-channel being formed between the multiple layers of dielectric, thus forming a charge trap FET. A charge trap complimentary current field-effect transistor (CFET) includes multiple layers of dielectric material defining a charge trapping layer and includes a 3D charge trap PFET formed with p+ symmetrical source/drain region formed over a 3D charge trap NFET formed with n+ symmetrical source/drain region.

### BACKGROUND

### Technical Field

This disclosure relates to microelectronic devices including semiconductor devices, transistors, and integrated circuits.

### Description of the Related Art

In the manufacture of a semiconductor device (especially on the microscopic scale), various fabrication processes are executed such as film-forming deposition, etch mask creation, patterning, material etching and removal, and doping treatments. These processes are performed repeatedly to form desired semiconductor device elements on a substrate. Historically, with microfabrication, transistors have been created in one plane, with wiring/metallization formed above the active device plane, and thus have been characterized as two-dimensional (2D) circuits or 2D fabrication. Scaling efforts have greatly increased the number of transistors per unit area in 2D circuits, yet scaling efforts are running into greater challenges as scaling enters single digit nanometer semiconductor device fabrication. Semiconductor device fabricators have expressed a desire for three-dimensional (3D) semiconductor circuits in which transistors are stacked on top of each other.

3D integration, i.e. the vertical stacking of multiple devices, aims to overcome scaling limitations experienced in planar devices by increasing transistor density in volume rather than area. Although device stacking has been successfully demonstrated and implemented by the flash memory industry with the adoption of 3D NAND devices, application to logic designs is substantially more difficult. 3D integration for logic chips (e.g., CPU (central processing unit), GPU (graphics processing unit), FPGA (field programmable gate array), SoC (System on a chip)) is being pursued.

### SUMMARY

Techniques herein include 3D architectures and methods of making 3D transistors using multiple selective nano-sheets for fabrication in different device regions (i.e. n-type MOS (NMOS), p-type MOS (PMOS), and new device types).

In particular, the techniques relate to a method of making a charge trap FET (both stacked NMOS FET and PMOS FET) to enable transistor types on multiple transistor planes. The FET device has very low sub-threshold slope (SS) and low power operation. By adding a fixed amount of controlled charge traps, improved custom device properties may be obtained for each transistor (i.e. robust transistor parameters, Vtcc, Idsat, Idoff). This allows for 3D integration since the transistor Vt may be altered by electrical programming to greatly expand logic options for 3D circuits.

Embodiments include charge trap field effect transistors (FETs) on multiple 3D nano-planes using stacked nano-sheets to make a FET charge trap transistor with a 3D device layout. The charge trap FET may be used to set threshold devices of NMOS and PMOS to optimize logic designs. The FET charge trap transistor may consist of a stack of multiple (e.g., one, two, or three) layers of dielectric to define the charge trapping layer in a nano-plane FET.

The charge trap feature allows the Vt to be set to various values to modulate the Vt by process conditions of charge trapping. Additionally, the charge trap FET can be electrically programmed and further re-programmed as needed to change the Vt to multiple values. This unique feature acts as a 3D switch. This feature may enable certain parts of the circuit to be modified for changing logic and circuit functions using the Vt to modulate the circuit (i.e., if the Vt of the charge trapped value is above the circuit Vt value, the transistor (charge trap FET) will be turned off)). Additionally, the 3D charge trap FET may also be used as a memory element in certain regions of the circuit.

A robust FET with charge trapping is beneficial to enable the FET to have optimum device properties (Idsat, Idoff, Vtcc). FET devices with low power and SS are needed for 3D memory circuits with 3D circuit logic, which is also the case for many other circuit designs. This application describes a method of making these devices on multiple nano-planes with different materials for effective circuit layout and design. Many other circuit logic blocks need the key elements discussed herein to become viable using nano-sheets and 3D device architecture.

Since the charge trap FET can be electrically programmed to change the Vt, unique logic elements (e.g., static random-access memory (SRAM), inverters, transistors and other essential logic blocks in 3D) can be made but also altered to establish a key 3D logic circuit where the logic and memory elements may be re-programmed for the specific circuit application.

The disclosure presented herein utilizes one or more dielectric stacks to create/optimize the charge trapping stack. The thickness and material types are customized for the specific circuit application and 3D CMOS device type.

The devices presented herein may include a 3D stack consisting of charge trap channels and non-charge trap channels.

Since the device type can be altered in the 3D stack and in different 3D circuit locations, this is advantageous to achieve higher Idsat and more options for Vt tuning and speed enhancements to enable a complete CMOS circuit solution.

Each transistor may have one channel as a minimum. Multiple charge trap channels may be combined to obtain more drive current as options with the charge trapping feature with variable Vt options.

Although each of the different features, techniques, configurations, etc., herein may be discussed in different places of this disclosure, it is intended that each of the concepts can be executed independently of each other or in combination with each other. Accordingly, the features of the present application can be embodied and viewed in many different ways.

This summary section does not specify every embodiment and/or novel aspect of the present application. Instead, this summary only provides a preliminary discussion of different embodiments and corresponding points of novelty over conventional techniques. Additional details and/or possible perspectives of the disclosed embodiments are described in the Detailed Description section and corresponding Figures of the present disclosure as further discussed below.

### BRIEF DESCRIPTION OF THE DRAWINGS

The application will be better understood in light of the description which is given in a non-limiting manner, accompanied by the attached drawings in which:

FIG. 1 shows a cross section of a nano-channel surrounded by a plurality of dielectric layers comprising the charge trapping layer and metal gate electrodes in a charge trap FET device. The cross section may be circular, square or rectangular.

FIG. 2 shows a table of dielectrics in a three dielectric layer stack for charge trapping.

FIG. 3 shows a table of dielectrics in a two dielectric layer stack for charge trapping.

FIG. 4 shows a table of dielectrics in a single dielectric layer stack for charge trapping.

FIG. 5 shows a schematic of a cross section of a charge trap FET gate oxide region showing the channel and three adjacent dielectric regions.

FIG. 6 shows a schematic of a cross section of a stack of two charge trap NFETs formed with n+ symmetrical S/D (with channel of intrinsic epi or p-type channel).

FIG. 7 shows a schematic of a cross section of a stack of two charge trap PFETs formed with p+ symmetrical S/D (with channel of intrinsic epi or n-type channel).

FIG. 8 shows a schematic of a cross section of a 3D charge trap CFET formed with p+ symmetrical S/D (with channel of intrinsic epi or n-type channel) over n+ symmetrical S/D (with channel of intrinsic epi or p-type channel).

FIG. 9 shows a cross section of the charge trap CFET gate oxide region showing the channel and three dielectric regions.

FIG. 10 shows a schematic of a cross section of a stack of two charge trap NFETs formed with n+ symmetrical S/D (with channel of n+ epi or n-type channel).

FIG. 11 shows a schematic of a cross section of a stack of two charge trap PFETs formed with p+ symmetrical S/D (with channel of p+ epi or p-type channel).

FIG. 12 shows a schematic of a cross section of a 3D charge trap CFET formed with p+ symmetrical S/D (with channel of p+ epi or p-type channel) over n+ symmetrical S/D (with channel of n+ epi or n-type channel).

FIG. 13 shows the device of FIG. 8 after metal gate stack formation.

FIG. 14 shows an expanded cross section of the device in FIG. 8.

FIG. 15 shows an expanded cross section of FIG. 12.

### DETAILED DESCRIPTION OF THE PREFERRED EMBODIMENTS

Reference throughout this specification to “one embodiment” or “an embodiment” means that a particular feature, structure, material, or characteristic described in connection with the embodiment is included in at least one embodiment of the application, but do not denote that they are present in every embodiment. Thus, the appearances of the phrases “in one embodiment” or “in an embodiment” in various places throughout this specification are not necessarily referring to the same embodiment of the application. Furthermore, the particular features, structures, materials, or characteristics may be combined in any suitable manner in one or more embodiments.

Embodiments described herein include a stack of transistor substrate planes to make a multi-dimensional logic circuit on multiple transistor planes. Devices herein are embodied using nano-channels. In general, the term “nano-channel” means either a nano-wire or a nano-sheet shaped channel for a field effect transistor. A nano-wire is a relatively small elongated structure formed having a generally circular cross section or rounded cross section. Nano-wires are often formed from layers that are pattern etched to form a channel having a generally square cross-section, and then corners of this square cross-section structure are rounded, such as by etching, to form a cylindrical structure. A nano-sheet is similar to a nano-wire in that it has a relatively small cross section (less than a micron and typically less than 30 nanometers), but with a cross section that is rectangular. A given nano-sheet can include rounded corners.

To date, a complete effective solution has not been demonstrated using stacked nano-sheets to make a FET charge trap transistor with a 3D device layout. Since the FET transistor can have a controlled amount of trapped charge, the Vt, Idsat, Idoff and other key device properties may be controlled on selective regions/locations of a circuit or even at the individual transistor level.

A current complementary FET (CFET) stack is a 2 layer stack (non trapping stack), with layer 1 an oxide and layer 2 an HfO₂ layer. The charge trap FET described here is compatible with the existing CFET. In one embodiment, the FET charge trap transistor consists of a stack of 3 layers of dielectric to define the charge trapping layer in a nano-plane FET.

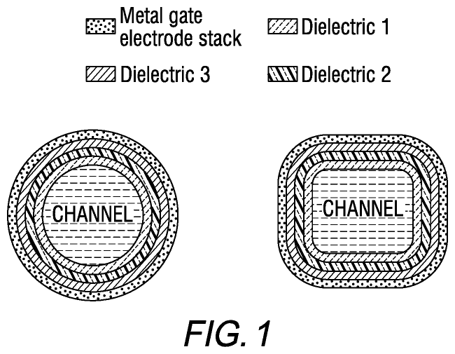

FIG. 1 shows a cross section of the nano-channel surrounded by the plurality of dielectric layers comprising the charge trapping layer. The cross section may be circular, square or rectangular.

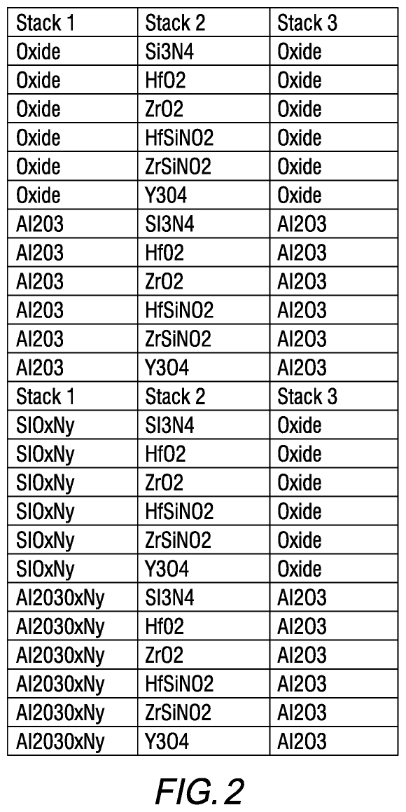

FIG. 2 shows examples of different materials that may be used to form the charge trap FET transistor. The material, thickness and properties for layer 1, layer 2, and layer 3 may be modified to tune and control the amount of charge trap in the FET to the desired properties needed for the circuit application. Additionally, the charge trap FET may be re-configured by biasing of the transistor to achieve different trapped charge states to optimize transistor performance in various regions of the circuit.

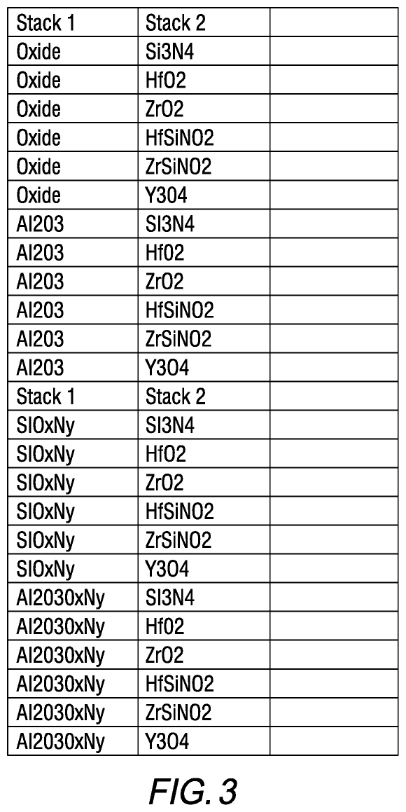

In another embodiment, the charge trapping layer comprises a stack of two layers of dielectric. FIG. 3 shows examples of different materials that may be used to form the charge trap FET transistor. For the 2 layer stack system, the high-k material of dielectric layer 2 is deposited to form charge traps that may be contained with just 2 dielectric depositions.

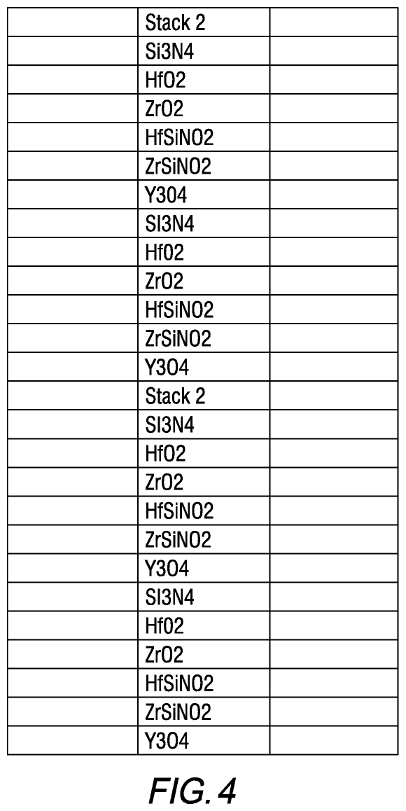

In still another embodiment, the charge trapping layer comprises one layer of dielectric. FIG. 4 shows examples of different materials that may be used to form the charge trap FET transistor. For the 1 layer stack system, the high k material is deposited to form charge traps with just one dielectric deposition.

Both the 2 layer dielectric deposition and 1 layer dielectric deposition can result in a 3 layer system (i.e. oxide interface/high k/oxide) that is generated by in-situ processing. Another option is that a 2 layer or 1 layer system can remain a 2 layer or 1 layer system with the use of the right gate electrode and dielectric combinations. After each dielectric is formed, an in-situ anneal is also an option to set the optimum amount of charge traps.

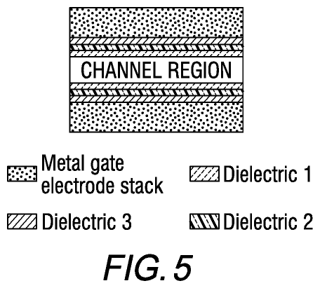

A typical 3 layer system is shown in FIG. 5 using HfO₂ as the second dielectric layer. In this example, the minimum 3 layer dielectric thickness is 0.9 nm, and the maximum 3 layer dielectric thickness is 3.5 nm. Also, since different high-k materials have a different k value, the physical thickness will change depending on which material is used.

Both the maximum and minimum thickness can be higher or lower depending on the circuit requirements (Vt, Idoff and Idsat). Also, since different high k materials have a different k value, the equivalent oxide thickness (EOT) is lower for HfO2 at a given HfO₂ thickness relative to SiO₂. It is noted that here, the higher k region is the charge trap layer.

The EOT of a layer is given by:

EOT=thickness of high k layer x (k of SiO2/k of high k layer)

In one example, for an HfO₂ layer of thickness 1.5 nm=15 A, the EOT is EOT=1.5 nm×(3.9/25)=0.234 nm=2.34 A oxide equivalent. That is, the thickness of HfO₂ at 15 A is equivalent to 2.34 A of oxide. By using higher k material, a charge trapping layer can be formulated with thicker physical thickness but small EOT.

Using the three stack dielectric deposition, a 3D stack of FET charge trapping devices can be made in either NMOS or PMOS devices. The method described herein has the ability to alter the Vt of the charge trap device either by changing the process conditions or by selectively programming the FET for the desired Vt window for optimum circuit performance.

In particular, the charge trap gate dielectric stack alone can alter the Vt of the device (material type, stack, and thickness). In addition, the metal gate material type work function alone can alter the Vt. The charge trap FET may use just one type of metal but also has a feature of Vt adjustment by adding or subtracting charge traps in the charge trap dielectric stack (for example, more positive charge in channel for NMOS would raise the Vt of NMOS but decrease the Vt of PMOS, and more negative charge in channel for PMOS would increase the Vt of PMOS but decrease the Vtof NMOS).

It is noted that a combination of the above three can be used to alter the Vt.

Many different metal depositions are possible with both NMOS and PMOS to achieve the desired Vt values for the specific circuit application. A feature of the present application is that one metal type is used for both NMOS and PMOS charge trap FET devices, which greatly reduces the process complexity. Some common metals that may be used are Ti, Ta, TiN, TaN, W, Ru, Pt, Co, NiSi, WSi, PtSi, and CoSi.

The range for the values of the altered Vt for NMOS FET may be, for example, from 0.2V to 1.5V and for PMOS FET from −0.2V to −1.5V (preferred range for low voltage (LV) logic circuits). However, the devices of the present application may cover higher voltage ranges for high voltage (HV) logic circuits. In general, an NMOS FET device has a positive Vt value and a PMOS FET has a negative Vt value. Any of the three Vt setting processes discussed above may establish a Vt value of 0.2V to 1.5V for NMOS and Vt value of −0.2V to −1.5V for PMOS.

In one embodiment of a three layer PMOS charge trap FET, the sequence of the layers and their thicknesses is shown below. Since the Vt can be tuned for each transistor, a large selection of metal gate electrode materials is possible:

Dielectric 1: 0.3 nm to 1.0 nm, interfacial oxide layer

Dielectric 2: 0.3 nm to 10.0 nm, HfO2, equivalent oxide thickness (EOT) range of 0.124 nm to 1.56 nm SiO2 equivalent for HfO2.

Dielectric 3: 0.3 nm to 1.0 nm, oxide layer

TiN: 0.9 nm

TaN: 0.9 nm

TiON: 2.7 nm

TiC: 2.7 nm

In one embodiment of a three layer NMOS charge trap FET, the sequence of the layers and their thicknesses is shown below.

Dielectric 1: 0.3 nm to 1.0 nm, interfacial oxide layer

Dielectric 2: 0.3 nm to 10.0 nm, HfO2, equivalent oxide thickness (EOT) range of 0.124 nm to 1.56 nm SiO2 equivalent for HfO2.

Dielectric 3: 0.3 nm to 1.0 nm, oxide layer

TiC: 2.7 nm

With some embodiments herein a nano-sheet stack is formed for gate-all-around stacked transistors. This can be, for example for a CFET 3D device. Starting material can be bulk silicon, bulk germanium, silicon on insulator (SOI), or other wafer or substrate. Multiple layers of material can first be formed as blanket depositions or epitaxial growth. In this example, nine layers of epitaxial growth are used. For example, layers of silicon, silicon germanium, and germanium in various molecular combinations can be grown, Si(65)Ge(35)/SixGey/Si/SixGey/Si/SixGey/Si/SixGey/Si, with typical ranges x from 0.6 to 0.8, and y from 0.4 to 0.2. Then, an etch mask is formed on top of the film stack. The film stack can be anisotropically etched to form nano-sheet stacks. Self-aligned double patterning or self-aligned quad patterning can be used to form an etch mask. Buried power rails can be formed. Additional microfabrication steps can include shallow trench isolation (STI) formation, creating dummy gates with poly silicon, selective SiGe release, depositing and etching low-k materials, and sacrificial spacer and inner spacer formation.

Techniques herein can be used with all 3D transistor types with a charge trapping layer. For example, symmetrical S/D NMOS, symmetrical S/D PMOS, S/D and channel one doping level for NMOS, PMOS. Any channel type dopant can be used. Embodiments include 3D or vertical stacking of trap channels. A given vertical stack of charge trapping channels can be of various types of FET deceives (PMOS, NMOS, CFET . . . ). Additionally, a given vertical stack of lateral gate-all-around channels can have some devices with charge trapping layers and other channels without (charge trap and non-charge trap). Because a device type can be altered in the 3D stack and different 3D circuit locations this is advantageous to achieve more Idsat, and more options for Vt tuning and speed enhancements to enable a complete CMOS circuit solution. Each transistor may have one channel as a minimum. Multiple N charge trap channels can be combined to obtain more drive current as options with the charge trapping feature with variable Vt options

As can be appreciated, various embodiments are possible including various device structures and method flows.

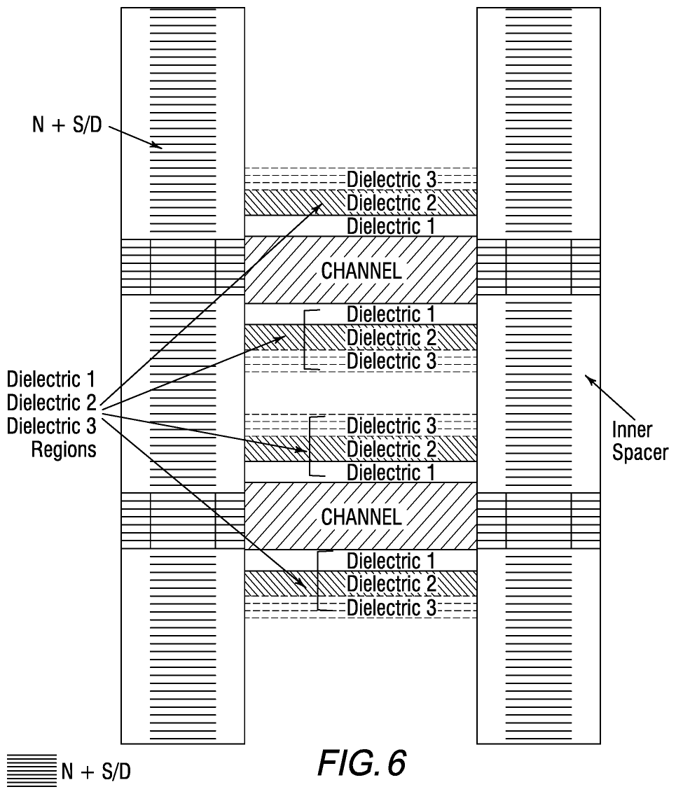

One embodiment includes a 3D charge trap NFET formed with n+ symmetrical S/D (with channel of intrinsic epi or p-type channel) (FIG. 6). In this embodiment, the NFET charge trap transistor consists of a stack of 3 layers of dielectric to define the charge trapping layer in a nano-plane NFET. In particular, for the NFET device, one source/drain region is n-doped, while the source/drain region on the opposite side is also n-doped. The one source/drain region is connected to the other source/drain region via a nano-channel, thus forming a charge trapping NFET. In FIG. 6, dielectric layer 1 (for example, oxide) is a tunneling dielectric layer; dielectric layer 2 (for example, a high k layer, e.g., HfO₂) is the charge trapping layer; and dielectric layer 3 (for example, oxide) is the charge retention layer. These layers may be formed using atomic layer deposition (ALD), but other methods may be used, including chemical vapor deposition (CVD).

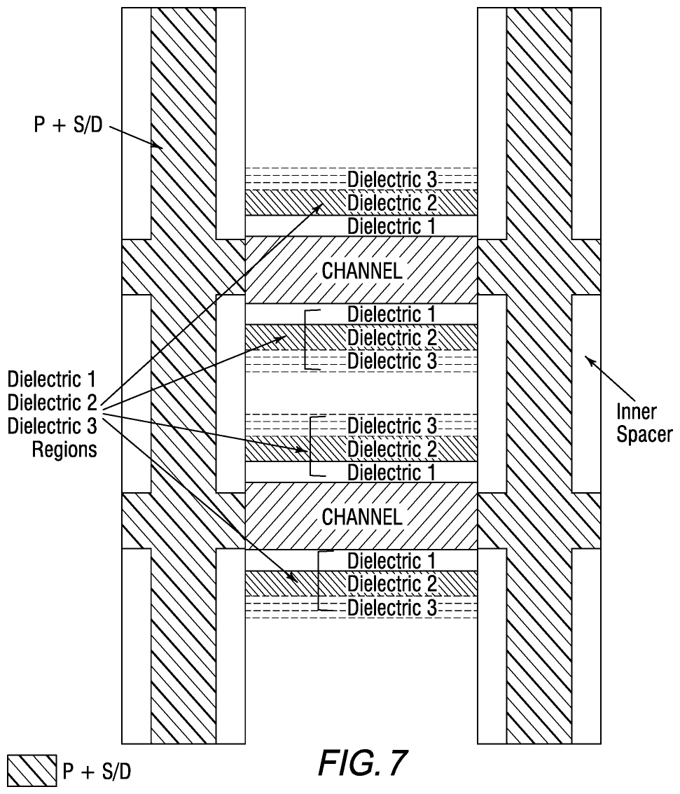

Another embodiment includes a 3D charge trap PFET formed with p+ symmetrical S/D (with channel of intrinsic epi or n-type channel) (FIG. 7). In this embodiment, the PFET charge trap transistor consists of a stack of 3 layers of dielectric to define the charge trapping layer in a nano-plane PFET. In particular, for the PFET device, one source/drain region is p-doped, while the source/drain region on the opposite side is also p-doped. The one source/drain region is connected to the other source/drain region via a nano-channel, thus forming a charge trapping PFET. In FIG. 7, dielectric layer 1 (for example, oxide) is a tunneling dielectric layer; dielectric layer 2 (for example, a high k layer, e.g., HfO₂) is the charge trapping layer; and dielectric layer 3 (for example, oxide) is the charge retention layer. These layers may be formed using ALD, but other methods may be used, including CVD.

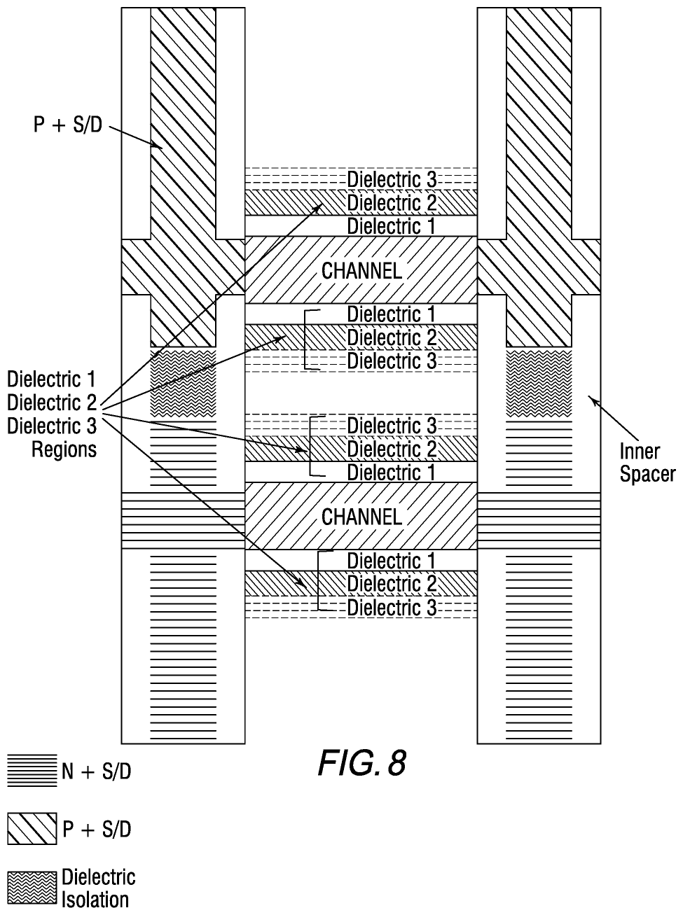

Another embodiment is a 3D charge trap CFET formed with p+ symmetrical S/D (with channel of intrinsic epi or n-type channel) over n+ symmetrical S/D (with channel of intrinsic epi or p-type channel) (FIG. 8). In this embodiment, the CFET charge trap transistor consists of stacks of 3 layers of dielectric to define the charge trapping layers in the nano-plane CFET. In particular, for the CFET device, one source/drain region is p-doped, while the source/drain region on the opposite side is also p-doped thus forming a p+ symmetrical S/D. In addition, for the CFET device, one source/drain region is n-doped, while the source/drain region on the opposite side is also n-doped thus forming an n+ symmetrical S/D. The p+ symmetrical S/D is formed over the n+ symmetrical S/D with dielectric isolation therebetween. The one source/drain region is connected to the other source/drain region via a nano-channel, thus forming a charge trapping CFET. In FIG. 8, dielectric layer 1 (for example, oxide) is a tunneling dielectric layer; dielectric layer 2 (for example, a high k layer, e.g., HfO₂) is the charge trapping layer; and dielectric layer 3 (for example, oxide) is the charge retention layer. These layers may be formed using ALD, but other methods may be used, including CVD.

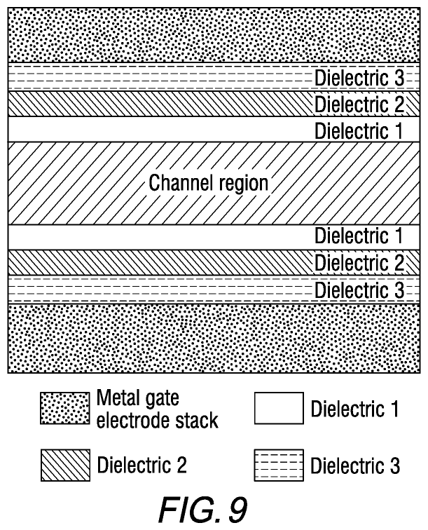

FIG. 9 shows a cross section of the above charge trap CFET gate oxide region showing the channel and three dielectric regions.

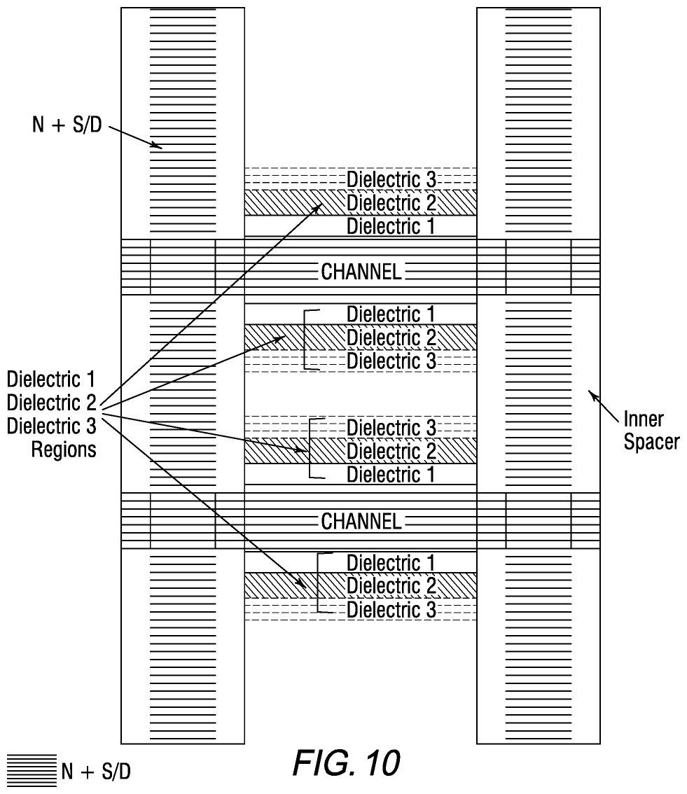

Another embodiment (FIG. 10) includes a 3D charge trap NFET (similar to that in FIG. 6) formed with n+ symmetrical S/D (with channel of n+ epi or n-type channel).

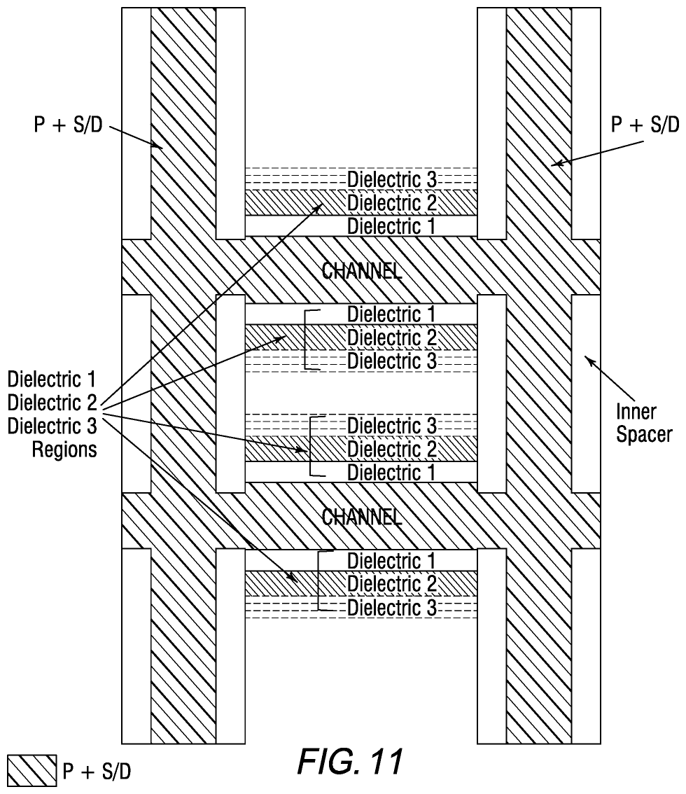

Another embodiment (FIG. 11) is a 3D charge trap PFET formed (similar to that in FIG. 7) with p+ symmetrical S/D (with channel of p+ epi or p-type channel).

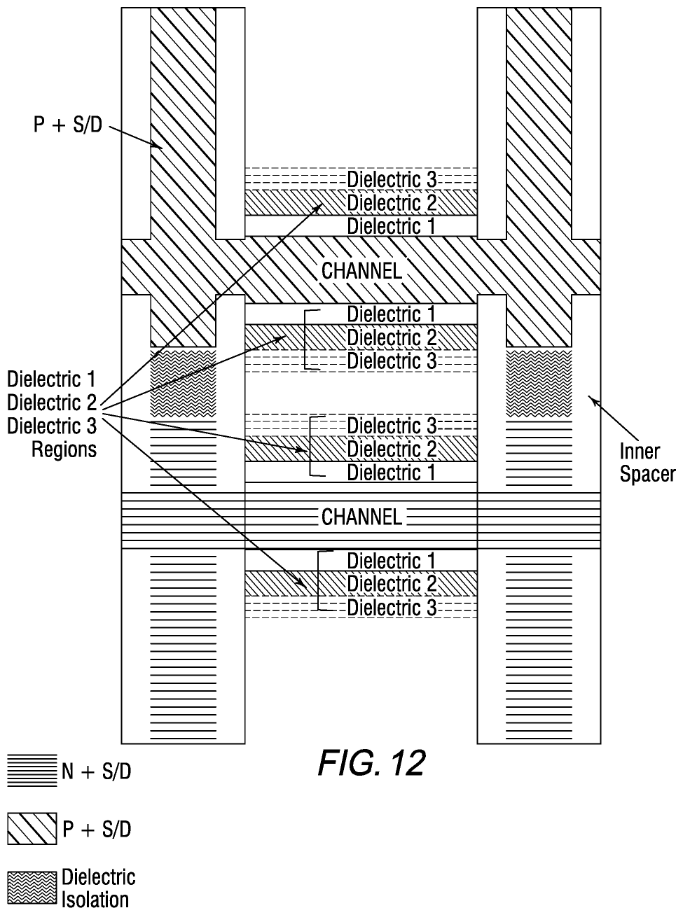

Still another embodiment comprises a charge trap CFET formed with a p+ symmetrical S/D (with channel of p+ epi or p-type channel) over an n+ symmetrical S/D (with channel of n+ epi or n-type channel) (FIG. 12).

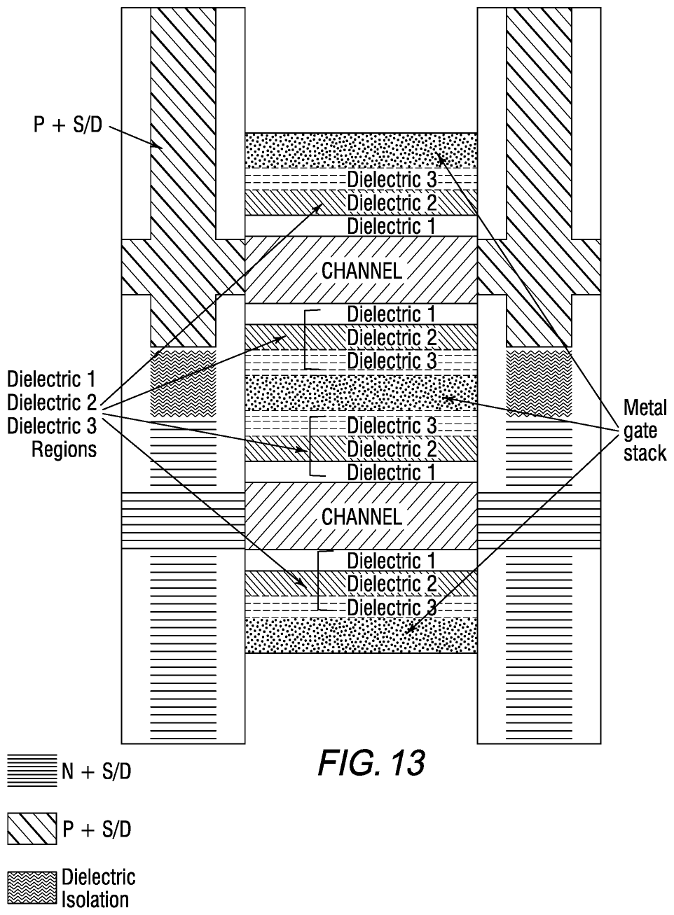

FIG. 13 shows the device of FIG. 8 after metal gate stack formation (metal gate electrode deposition) between the nano-channels of the PFET and the NFET and between the opposite source/drain sides of the PFET and the NFET. More stacks with charge trap CFETs are possible.

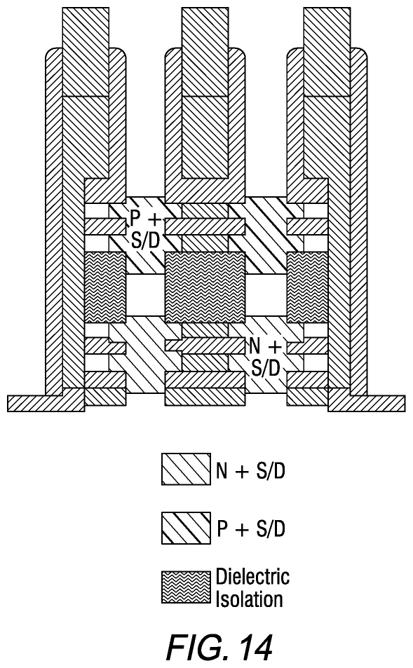

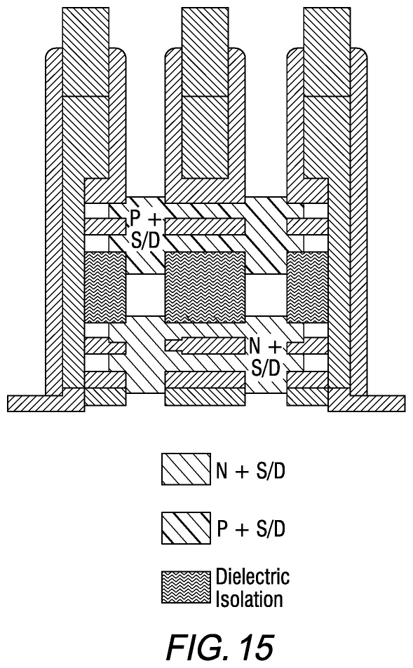

FIG. 14 shows an expanded cross section of FIG. 8 and FIG. 15 shows an expanded cross section of FIG. 12, showing the charge trap CFET after formation of S/D sections.

Accordingly, techniques herein use one or more dielectric stacks to create/optimize a charge trapping stack. The thickness and material types are customized for the specific circuit applications and various 3D CMOS device types. Embodiments herein can include a vertical stack of FETs with trap channels only, and also a stack of combinations of the new devices (charge trap and non-charge trap). Because the device type can be altered in the 3D stack and different 3D circuit locations, this is advantageous to achieve more Idsat, and more options for Vt tuning and speed enhancements to enable a complete CMOS circuit solution.

Advantages of the charge trap FET described herein include: 1) by optimization of a precisely controlled charge trap population, a stable transistor with predicable transistor properties can be achieved (i.e. Ids vs Vt, Idoff vs Idsat); 2) lower SS and better performance with charge trap FET devices (drive current is available per area of chip layout); 3) multiple and stable Vt values for low voltage; 4) new transistor architectures will enable N=1 to N≥10 substrate planes of transistors depending on circuit requirements; 5) the charge trap FET of the present application may be co-integrated with existing CFET with a few extra process steps. The new charge trapping tunneling transistor will be needed for future scaling for low power and channel length scaling.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the present application. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives. Such variations are intended to be covered by the scope of this disclosure. As such, the foregoing descriptions of the embodiments are not intended to be limiting. Rather, any limitations to the embodiments are presented in the following claims.

1: A semiconductor device comprising:
a stack of field-effect transistors (FETs) formed on a substrate, the stack extending perpendicular to a surface of the substrate, each FET in the stack of FETs including one nano-channel that connects one source/drain region on a first side of the FET with another source/drain region on an opposite side of the FET, wherein at least one dielectric layer is formed around the nano-channel, the at least one dielectric layer forming a charge trapping layer.

2: The semiconductor device according to claim 1, wherein each FET in the stack of FETs is an n-type field-effect transistor (NFET).

3: The semiconductor device according to claim 1, wherein each FET in the stack of FETs is a p-type field-effect transistor (PFET).

4: The semiconductor device according to claim 1, wherein
the at least one dielectric layer comprises a first oxide layer formed around the nano-channel, a high dielectric constant (k) dielectric layer formed around the first oxide layer, and a second oxide layer formed around the high k dielectric layer.

5: The semiconductor device according to claim 1, wherein
the at least one dielectric layer comprises a first oxide layer formed around the nano-channel, and a high dielectric constant (k) dielectric layer formed around the first oxide layer.

6: The semiconductor device according to claim 1, wherein
the at least one dielectric layer comprises a high dielectric constant (k) dielectric layer formed around the nano-channel.

7: The semiconductor device according to claim 4, wherein the high k dielectric layer is HfO₂.

8: The semiconductor device according to claim 5, wherein the high k dielectric layer is HfO₂.

9: The semiconductor device according to claim 6, wherein the high k dielectric layer is HfO₂.

10. The semiconductor device according to claim 2, wherein the nano-channel is a channel of intrinsic epi or p-type channel.

11. The semiconductor device according to claim 2, wherein the nano-channel is a channel of doped n epi or n-type channel.

12. The semiconductor device according to claim 3, wherein the nano-channel is a channel of intrinsic epi or n-type channel.

13. The semiconductor device according to claim 3, wherein the nano-channel is a channel of doped p epi or p-type channel.

14. The semiconductor device according to claim 1, wherein each FET in the stack of FETs is either an n-type field-effect transistor (NFET) or a p-type field-effect transistor (PFET).

15: A semiconductor charge trap current complimentary field-effect transistor (CFET) device comprising:
an n-type field effect transistor (NFET) formed on a substrate, the NFET including one nano-channel that connects source/drain regions of the NFET, wherein at least one dielectric layer is formed around the nano-channel, the at least one dielectric layer forming a charge trapping layer; and
a p-type field effect transistor (PFET) formed on the substrate and positioned directly above the NFET with at least one spacer separating the NFET from the PFET, the PFET including one nano-channel that connects source/drain regions of the PFET, wherein at least one dielectric layer is formed around the nano-channel, the at least one dielectric layer forming a charge trapping layer, wherein
the drain region of the PFET is connected to the source region of the NFET via dielectric isolation therebetween.

16: The semiconductor device according to claim 15, wherein
the nano-channel of the PFET is a channel of intrinsic epi or n-type channel and the nano-channel of the NFET is a channel of intrinsic epi or p-type channel, or the nano-channel of the PFET is a channel of doped p epi or p-type channel and the nano-channel of the NFET is a channel of doped n epi or n-type channel.

17: The semiconductor device according to claim 15, wherein
a stack of metal gate electrodes are formed between opposite source/drain regions of the NFET and between opposite source/regions of the PFET, and between the nano-channels of the NFET and the PFET in a direction normal to the surface of the substrate.

18: The semiconductor device according to claim 15, wherein
the at least one dielectric layer comprises a first oxide layer formed around the nano-channel, a high dielectric constant (k) dielectric layer formed around the first oxide layer, and a second oxide layer formed around the high k dielectric layer.

19: The semiconductor device according to claim 15, wherein
the at least one dielectric layer comprises a first oxide layer formed around the nano-channel, and a high dielectric constant (k) dielectric layer formed around the first oxide layer.

20: The semiconductor device according to claim 15, wherein
the at least one dielectric layer comprises a high dielectric constant (k) dielectric layer formed around the nano-channel.
